(19) United States
(12) Patent Application Publication
(10) Pub. No.: US 2007/0063277 A1
(43) Pub. Date: Mar. 22, 2007

(54) MULTIPLE LOW AND HIGH K GATE OXIDES ON SINGLE GATE FOR LOWER MILLER CAPACITANCE AND IMPROVED DRIVE CURRENT

(75) Inventors: Michael P. Belyansky, Bethel, CT (US); Dureseti Chidambarrao, Weston, CT (US); Omer H. Dokumaci, Wappingers Falls, NY (US); Oleg Gluschenkov, Poughkeepsie, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/162,778

(22) Filed: Sep. 22, 2005

(51) Int. Cl. H01L 27/12; H01L 27/01; H01L 31/0392

(52) U.S. Cl. 257/347

(57) ABSTRACT

The present invention provides a semiconductor structure having at least one CMOS device in which the Miller capacitances, i.e., overlap capacitances, are reduced and the drive current is improved. The inventive structure includes a semiconductor substrate having at least one overlaying gate conductor, each of the at least one overlaying gate conductors has vertical edges; a first gate oxide located beneath the at least one overlaying gate conductor, the first gate oxide not extending beyond the vertical edges of the at least overlaying gate conductor; and a second gate oxide located beneath at least a portion of the at one overlaying gate conductor. In accordance with the present invention, the first gate oxide and the second gate oxide are selected from high k oxide-containing materials and low k oxide-containing materials, with the proviso that when the first gate oxide is high k, than the second gate oxide is low k, or when the first gate oxide is low k, than the second gate oxide is high k.

### FIELD OF THE INVENTION

The present invention relates to a semiconductor structure including at least one complementary metal oxide semiconductor (CMOS) device and more particular to a semiconductor structure comprising at least one CMOS device in which the Miller capacitances have been reduced below values of conventional CMOS devices. The present invention also relates to methods of fabricating such a semiconductor structure.

### BACKGROUND OF THE INVENTION

In the semiconductor industry, there is a constant demand to increase the operating speed of integrated circuits (ICs). This increased demand is fueled by the need for electronic devices such as computers to operate at increasingly greater speeds. The demand for increased speed, in turn, has resulted in a continual size reduction of the semiconductor devices. Specifically, the channel length, junction depths, and/or gate dielectric thickness of field effect transistors (FETs) are reduced. Thus, there is a constant drive to reduce the size, or scale, of the components of a typical FET to increase the overall speed of the FET. Additionally, reducing the size, or scale, of the components of a typical FET also increases the density and number of FETS that can be fabricated on a given single semiconductor wafer.

However, reducing the channel length of a transistor also increases “short-channel” effects, as well as “edge effects” that are relatively unimportant in long channel transistors. Short-channel effects include, among other things, an increased source/drain (S/D) leakage current when the transistor is switched “off”. One of the edge effects that may influence transistor and circuit performance is known as the total gate-to-drain and gate-to-source capacitance. Gate-drain capacitance is also known as “Miller capacitance” due to a Miller multiplication factor, which increases the capacitance by a factor related to the voltage gain of a transistor. The Miller multiplication further increases the parasitic gate-to-drain capacitance that slows down circuits. As is known to those skilled in the art, the large portion of gate-to-drain and gate-to-source or Miller capacitances is an overlap capacitance that arises because the gate conductor almost invariably overlaps, with a conductive portion of either the deep S/D regions or, if present, the S/D extension regions.

In order for further scaling of FETs, there is a need to reduce the gate-to-drain and gate-to-source or Miller capacitances of the FET without any detrimental effect on transistor drive current. To date, there is no suitable technique available in the art that reduces the overlap capacitances of FETs, which, in turn, will provide improved switching speed of a circuit.

### SUMMARY OF THE INVENTION

The present invention provides a semiconductor structure including a CMOS device in which the gate-to-drain and gate-to-source or Miller capacitances are reduced using a combination of high k and low k oxide-containing dielectrics. The term “high k” as used throughout the present application denotes an oxide-containing material whose thickness-averaged dielectric constant is about 6.0 or greater, preferably greater than 7.0. The term “low k” denotes an oxide-containing material whose dielectric constant is less than 6.0, preferably less than 5.0. All dielectric constants mentioned herein are relative to a vacuum unless otherwise noted.

In broad terms, the inventive semiconductor structure comprises:

a semiconductor substrate having at least one overlaying gate conductor, each of said at least one overlaying gate conductors has vertical edges;

a first gate oxide located beneath said at least one overlaying gate conductor, said first gate oxide not extending beyond the vertical edges of said at least one overlaying gate conductor; and

a second gate oxide located beneath at least a portion of said at least one overlaying gate conductor, wherein said first gate oxide and second gate oxide are selected from high k oxide-containing materials and low k oxide-containing materials, with the proviso that when the first gate oxide is high k, than the second gate oxide is low k, or when the first gate oxide is low k, than the second gate oxide is high k.

In addition to the above structure, the present invention also provides various methods of fabricating the same. In one method, the processing steps comprise:

providing a semiconductor substrate having at least one overlaying gate conductor and a first gate oxide located beneath said at least one overlaying gate conductor, each of said at least one overlaying gate conductors having vertical edges;

recessing said first gate oxide to provide an undercut region beneath each gate conductor; and

forming a second gate oxide in at least said undercut region, wherein said first gate oxide and second gate oxide are selected from high k oxide-containing materials and low k oxide-containing materials, with the proviso that when the first gate oxide is high k, than the second gate oxide is low k, or when the first gate oxide is low k, than the second gate oxide is high k.

Another method of the present invention, which is referred to herein as a replacement gate process, comprises the steps of:

providing a planarized structure comprising a semiconductor substrate, a sacrificial oxide on said semiconductor substrate, a patterned sacrificial polysilicon region on a portion of said sacrificial oxide and a dielectric material on other portions of said sacrificial oxide;

removing said patterned sacrificial polysilicon region to provide an opening in said planarized structure and to expose a surface portion of the sacrificial oxide;

forming a sacrificial spacer on sidewalls of said dielectric material in said opening;

removing said exposed surface portion of the sacrificial oxide from said opening so as to form an undercut beneath said sacrificial spacer;

forming a second gate oxide that fills said undercut;

forming a first gate oxide in said opening on exposed surface portions of said semiconductor substrate;

removing said sacrificial spacer;

forming a gate conductor in said opening; and

etching back at least said dielectric material.

### BRIEF DESCRIPTION OF THE DRAWINGS

FIGS. 1A-1E are pictorial representations (through cross sectional views) illustrating basic processing steps of the one embodiment of the present invention.

FIGS. 2A-2G are pictorial representations (through cross sectional views) illustrating basic processing steps of another embodiment of the present invention.

FIG. 3 is a pictorial representation (through a cross sectional view) illustrating a structure having asymmetric undercut regions in which the drain (D) undercut is larger than the source (S) undercut.

### DETAILED DESCRIPTION OF THE INVENTION

The present invention, which provides a structure and methods for lowering gate-to-drain and gate-to-source or Miller capacitances and improving drive current of a CMOS device, will now be described in greater detail by referring to the drawings that accompany the present application. It is noted the drawings of the present application are provided for illustrative purposes and thus they are not drawn to scale.

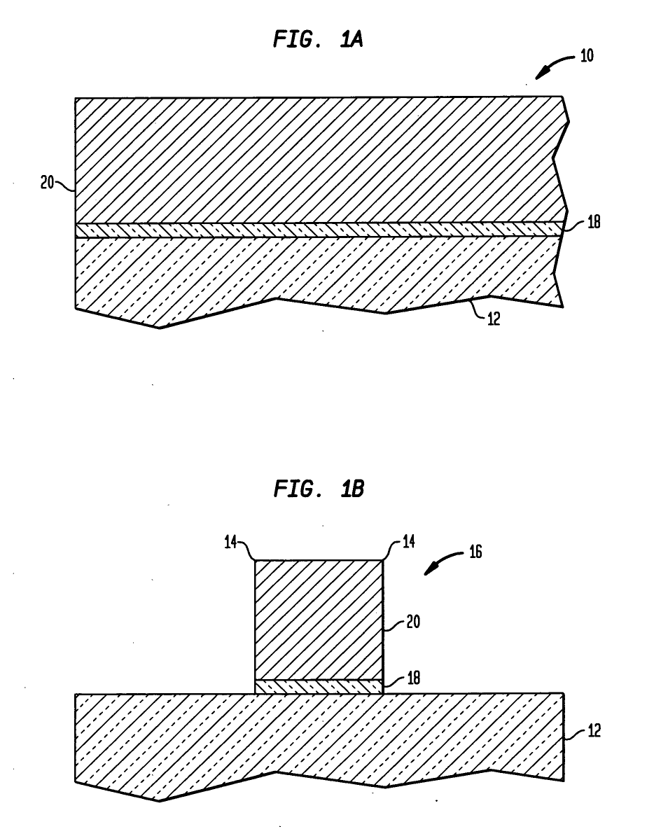

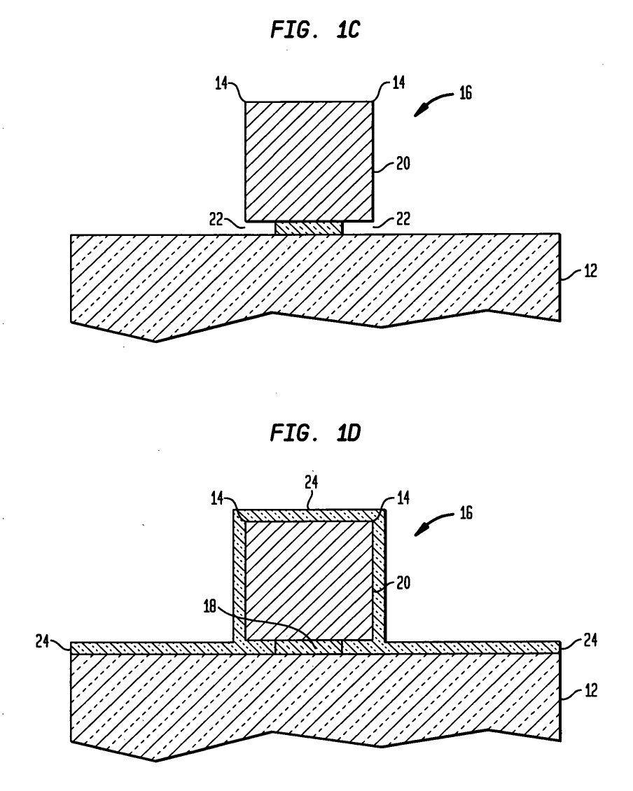

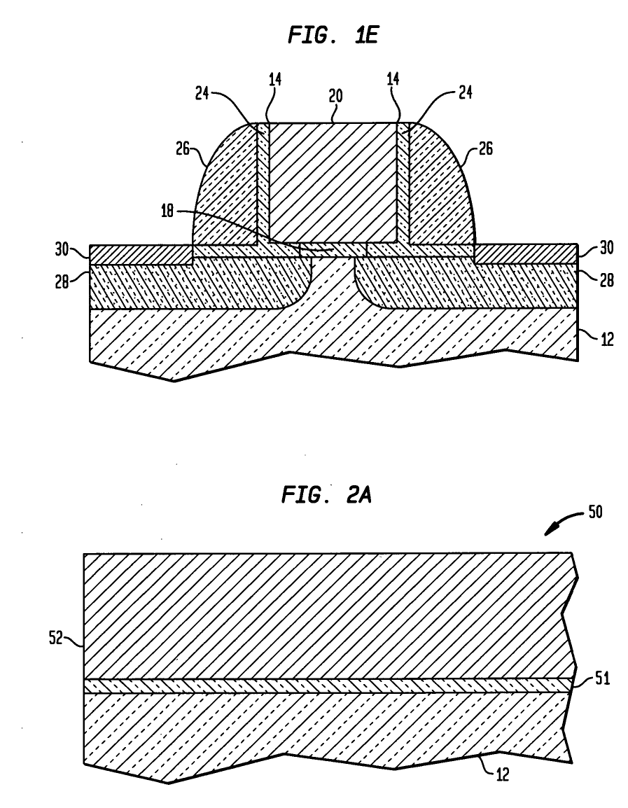

Reference is first made to FIGS. 1A-1E which illustrate a first method contemplated by the present invention for fabricating a semiconductor structure in which reduced gate-to-drain and gate-to-source or Miller capacitances and improved drive current of a CMOS device is achieved.

FIG. 1A illustrates an initial structure 10 that is employed in this embodiment of the present invention. As illustrated, the structure 10 includes a semiconductor substrate 12 that has blanket layers of a first gate oxide 18 and a gate conductor 20 located thereon. The blanket layers 18 and 20 are used in forming at least one gate region 16 see, FIG. 1B. The at least one gate region 16 is provided for illustrative purposes and thus the present invention is not limited to only a single gate region. Instead, the present invention works when the substrate includes a plurality of gate regions.

The semiconductor substrate 12 of structure 10 comprises any semiconducting material including, but not limited to: Si, Ge, SiGe, SiC, SiGeC, Ga, GaAs, InAs, InP and all other III/V compound semiconductors. Semiconductor substrate 12 may also comprise an organic semiconductor or a layered semiconductor such as Si/SiGe, a silicon-on-insulator (SOI) or a SiGe-on-insulator (SGOI). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein.

The semiconductor substrate 12 may also include a first doped (n- or p-) region, and a second doped (n- or p-) region. For clarity, the doped regions are not specifically labeled in the drawings of the present application. The first doped region and the second doped region may be the same, or they may have different conductivities and/or doping concentrations. These doped regions are known as “wells”.

Trench isolation regions (not shown) are typically already formed in the semiconductor substrate 12 at this point of the present invention utilizing conventional processes well known to those skilled in the art. The trench isolation regions are typically formed utilizing trench isolation techniques that are well known in the art including, for example, forming a patterned mask on the surface of the substrate via lithography, etching a trench into the substrate thru an opening in the patterned mask, filling the trench with a trench dielectric such as SiO₂ or TEOS and planarizing the structure. An optional trench liner can be formed within the trench prior to trench dielectric fill and an optional densification step may follow the planarization process.

Other useful structures (not shown) can also be present in the substrate 12 at this point of the present invention. These structures may include trench capacitors, memory cells, epitaxial islands of different crystal orientation or rotation. Although useful, such structures are not essential to the present invention.

Prior to forming the gate dielectric 18, the surface of substrate 12 is cleaned to remove any residual layers (e.g., native oxide), foreign particles, and any residual metallic surface contamination and to temporarily protect the cleaned substrate surface. The residual silicon oxide is first removed in a solution of hydrofluoric acid. The preferred removal of particles and residual metallic contamination is based on the industry standard gate dielectric preclean known as RCA clean. The RCA clean includes a treatment of the substrate 12 in a solution of ammonium hydroxide (NH₄OH) and hydrogen peroxide (H₂O₂) followed by an aqueous mixture of hydrochloric acid and an oxidizing agent (e.g., H₂O₂, O3). As a result, the cleaned substrate surface is sealed with a very thin layer of chemical oxide. While the protective chemical oxide is typically made thinner than about 10 Å so to not interfere with the properties of gate dielectric layer 18, its thickness can be varied to beneficially alter properties of the gate dielectric layer 18.

A first gate oxide 18 is formed on the entire surface of the structure 10 including the semiconductor substrate 12 and atop the isolation region, if it is present and, if it is a deposited dielectric. The first gate oxide 18 can be formed by a thermal growing process such as, for example, oxidation. Alternatively, the first gate oxide 18 can be formed by a deposition process such as, for example, chemical vapor deposition (CVD), plasma-assisted CVD, atomic layer or pulsed deposition (ALD or ALPD), evaporation, reactive sputtering, chemical solution deposition or other like deposition processes. The first gate oxide 18 may also be formed utilizing any combination of the above processes.

The first gate oxide 18 is comprised of an oxide-containing insulating material that has a first dielectric constant that is either low k or high k. The term “high k” as used throughout the present application denotes an oxide-containing material whose thickness-average dielectric constant is about 6.0 or greater, preferably greater than 7.0. The term “low k” as used throughout the present invention denotes an oxide-containing material whose dielectric constant is less than 6.0, preferably less than 5.0.

Illustrative examples of low k oxide-containing materials include, for example, pure SiO₂, SiON with thickness-averaged nitrogen content of less than about 25 atomic percent, carbon-doped SiO₂:C comprising atoms of at least Si, C and O, where carbon content is less than about 30 atomic percent. A highly preferred low k oxide-containing material employed in the present invention is SiO₂. Illustrative high k gate oxide-containing materials include, for example, silicon oxide or oxynitride compounds doped with transitional metal atoms such compounds of HfₓSi₁₋ₓO₂, TiₓSi₁₋ₓO₂, LaₓSi₁₋ₓO₂, ZrₓSi₁₋ₓO₂ or dielectric stacks comprised of layers of insulation metal oxides such as Al₂O₃, TiO₂, Ta₂O₃, HfO₂, La₂O₃, Y₂O₃, perovskite type oxides SrTiO₃ or LaAlO₃, and mixtures thereof. A highly preferred high k oxide-containing materials employed in the present invention are transitional metal silicates with a low content of transitional atoms such as HfₓSi₁₋ₓO₂, TiₓSi₁₋ₓO₂, LaₓSi₁₋ₓO₂, and ZrₓSi₁₋ₓO₂ with x less than about 0.3.

The physical thickness of the first gate oxide 18 may vary, but typically, the first gate oxide 18 has a thickness from about 0.5 to about 10 nm, with a thickness from about 0.5 to about 2 nm being more typical.

After forming the first gate oxide 18, a blanket layer of polysilicon or another gate conductor material or combination thereof, which becomes the gate conductor 20 shown in FIG. 1A, is formed on the first gate oxide 18 utilizing a known deposition process such as, for example, physical vapor deposition, CVD or evaporation. The blanket layer of gate conductor material may be doped or undoped. If doped, an in-situ doping deposition process may be employed in forming the same. Alternatively, a doped gate conductor layer can be formed by deposition, ion implantation and annealing. The doping of the gate conductor layer will shift the workfunction of the gate formed. Illustrative examples of dopant ions include As, P, B, Sb, Bi, In, Al, Ga, Tl or mixtures thereof. Typical doses for the ion implants are 1 E14(=1×10¹⁴) to 1 E16(=1×10¹⁶) atoms/cm² or more typically 1 E15 to 5E15 atoms/cm². The thickness, i.e., height, of the gate conductor 20 deposited at this point of the present invention may vary depending on the deposition process employed. Typically, the gate conductor 20 has a vertical thickness from about 20 to about 180 nm, with a thickness from about 40 to about 150 nm being more typical.

The gate conductor 20 can comprise any conductive material that is typically employed as a gate of a CMOS structure. Illustrative examples of such conductive materials that can be employed as the gate conductor 20 include, but are not limited to: polysilicon, conductive metals or conductive metal alloys, conductive silicides, conductive nitrides, polySiGe and combinations thereof, including multilayers thereof. In some embodiments, it is possible to form a barrier layer between multiple layers of gate conductors.

An optional dielectric cap (not shown) can be formed atop the gate conductor 20 at this point of the present invention. The optional dielectric cap is typically removed before or immediately after the source/drain regions to be subsequently formed have been silicided.

The blanket gate conductor 20 and the first gate oxide 18 are then patterned by lithography and etching so as to provide at least one patterned gate stack 16, as shown in FIG. 1B. When a plurality of patterned gate stacks is present, the patterned gate stacks may have the same dimension, i.e., length, or they can have variable dimensions to improve device performance. Each patterned gate stack at this point of the present invention includes at least the gate conductor 20 and the first gate oxide 18. The lithography step includes applying a photoresist to the upper surface of the gate conductor 20, exposing the photoresist to a desired pattern of radiation and developing the exposed photoresist utilizing a conventional resist developer. The pattern in the photoresist is then transferred to the blanket layer of gate conductor 20 and the first gate oxide 18 utilizing one or more dry etching steps. In some embodiments, the patterned photoresist may be removed after the pattern has been transferred into the blanket layer of gate conductor 20.

In the drawings, reference numeral 14 denotes the gate edge or the vertical sidewalls of the patterned gate conductor 20.

Suitable dry etching processes that can be used in the present invention in forming the patterned gate stacks include, but are not limited to: reactive ion etching, ion beam etching, plasma etching or laser ablation. A wet or dry etching process can also be used to remove portions of the first gate oxide 18 that are not protected by the patterned gate conductor 20.

Next, and as shown in FIG. 1C, the structure including the patterned gate region 16 is subjected to an etching process that selectively removes a portion of the previously patterned first gate oxide 18 so as to provide an undercut region 22 beneath the patterned gate conductor 20. As shown, this step of the present invention reduces the length of the previously patterned first gate oxide 18 from the original structure shown in FIG. 1B.

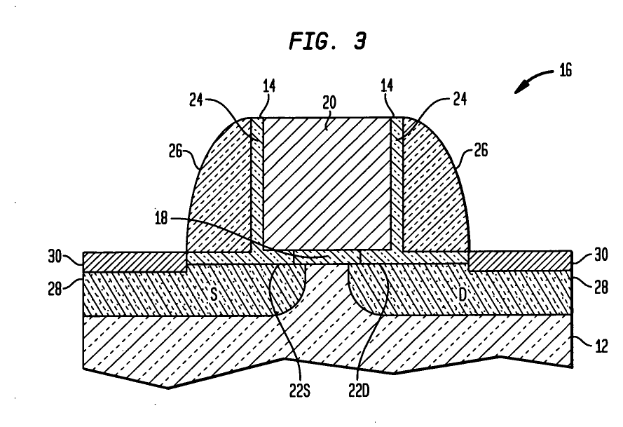

The undercut region 22 does not have to be too large provided that the edges of the first gate oxide 18, after the etch, are not aligned with the vertical sidewalls, e.g., edges, 14 of the patterned gate conductor 20. A typical undercut dimension is from about 10 Å to about 40 Å with respect to the gate conductor edge. The etching step used in forming the undercut region 22 comprises a chemical oxide removal (COR) process wherein a vapor, or more preferably, a plasma of HF and NH₃ is employed as the etchant and low pressures (on the order of about 6 millitorr or less) are used. In addition to the COR process, the present invention also contemplates utilizing other types of etching processes such as a reactive ion etching process with a large isotropic component that can provide the undercut region 22 shown in FIG. 1C. Alternatively, a simple diluted HF-base wet solution can be used to slowly etch out the first gate oxide 18. Optionally, an angled ion implantation can be used to create damage in first gate oxide 18 to control and facilitate removal of a desired portion of the first gate oxide 18. Large ions such as Ar+, Xe+, As+, Ge+ can be employed for this purpose. Typical damage-inducing dose is from 5E14 cm⁻² to 5E15 cm⁻². A typical implantation energy depends on a particular choice of ion but should not exceed 20 KeV. The ion implant tilt angle can be employed to control the amount of undercut. The typical implant tilt angle range is from about 5° to about 45°. Further, an asymmetric undercut can be easily produced by implanting damage-inducing ions at different angles from different sides of the gate. Specifically, a larger undercut is preferred from the drain side of a transistor due to Miller multiplication factor as alluded above. A structure including a large drain (D) undercut 22D and a smaller source (S) undercut 22S is shown in FIG. 3.

A second gate oxide 24, which is either a high k oxide-containing material or a low k oxide-containing material, is then formed over the entire structure forming the structure shown in FIG. 1D. Note that the second gate oxide 24 fills the undercut region 22 provided by the previous etching step.

In accordance with the present invention, the second gate oxide 24 must have a different dielectric constant than the first gate oxide 18, yet it must fall within either the high or low k regime above. Hence, if the first gate oxide 18 is a low k oxide-containing material, then the second gate oxide 24 must be a high k oxide-containing material. Conversely, if the first gate oxide 18 is a high k oxide-containing material, then the second gate oxide 24 must be a low k oxide-containing material.

The second gate oxide 24 can be formed by a thermal growing process such as, for example, oxidation. Alternatively, the second gate oxide 24 can be formed by a deposition process such as, for example, chemical vapor deposition (CVD), plasma-assisted CVD, atomic layer deposition (ALD), evaporation, reactive sputtering, chemical solution deposition or other like deposition processes. The second gate oxide 24 may also be formed utilizing any combination of the above processes. The physical thickness of the second gate oxide 24 may vary, but typically, the second gate oxide 24 has a thickness from about 0.5 to about 10 nm, with a thickness from about 0.5 to about 2 nm being more typical. Note that in the embodiment illustrated the second gate oxide 24, in addition to filling the undercut region 22, covers the sidewalls 14 and the top surface of the gate conductor 20. In yet other embodiments, the second gate oxide 24 is not located on the top surface of the gate conductor 20. In yet other embodiments, the second gate oxide 24 is not located on the sidewalls 14 or the top of the gate conductor 20.

After forming the structure shown in FIG. 1D, further CMOS processing can be used to complete the fabrication of the field effect transistor. For example, spacer formation, source/drain region formation, silicide contact formation and other like processing steps can be employed. FIG. 1E shows the structure after spacer 26 formation, source/drain region 28 formation and silicide contact 30 formation.

In the embodiment illustrated, the at least one spacer 26 is formed on exposed sidewalls of each patterned gate stack 16 that include the second gate oxide 24. The at least one spacer 26 is comprised of an insulator such as an oxide, nitride, oxynitride, or carbon-containing silicon oxide, nitride, oxynitride, and/or any combination thereof. The at least one spacer 26 is formed by deposition and etching. During the etching process, the second gate oxide 24 not protected by spacer 26 can be removed. This embodiment is illustrated in the drawing of the present invention.

The width of the at least one spacer 26 must be sufficiently wide enough such that the source and drain silicide contacts (to be subsequently formed) do not encroach underneath the edges of the gate stack. Typically, the source/drain silicide does not encroach underneath the edges of the gate stack when the at least one spacer has a width, as measured at the bottom, from about 15 to about 80 nm.

After spacer formation, source/drain diffusion regions 28 are formed into the substrate 12. The source/drain diffusion regions 28 are formed utilizing ion implantation and an annealing step. The annealing step serves to activate the dopants that were implanted by the previous implant step. Further, the annealing step serves to accurately diffuse source/drain dopants to create an overlap between source/drain and gate conductor. The amount of this gate-to-source and gate-to-grain overlap is critical to obtain high drive current of the transistor. Accordingly, the position of the source/drain-to-channel p-n junction is located about 1 to about 4 nm from the gate conductor edge 14 in order to obtain high drive current of a MOS transistor.

In the present invention, the phrase “source/drain diffusion regions” includes extension regions, halo regions and deep source/drain regions. Note that it is possible to form the source/drain extension regions prior to forming the at least one spacer 26. Shallow source/drain extension regions are typically employed to set a desirable gate overlap per given anneal condition. The exact implantation conditions for the source/drain extension is therefore a function of spacer 26 thickness, desired gate conductor overlap, and the anneal condition (temperature and time). The functional dependence between these parameters is well known to those skilled in the art. Further, it can be easily experimentally mapped for any specific case of desired overlap. Typically, the extension does is varied from about 3E14 cm⁻² to about 3E15 cm⁻², the spacer thickness is varied from about 1 nm to about 20 nm, the anneal temperature is varied from about 900° C. to about 1150° C., and the anneal time is varied from 0 sec (spike anneal) to about 10 sec to obtain the gate overlap (typically, measured via gate overlap capacitance) as function of these parameters.

The conditions for source/drain regions away from the gate conductor edge are chosen to minimize parasitic series resistance and any junction capacitance. Specifically, these source/drain regions are made deep (from about 300 Å to about 700 Å deep) and heavily doped (with average concentration of dopants from about 5E19cm⁻³ to about 1 E21 cm⁻³) to reduce series and contact resistances of the transistor. In certain technologies where junction capacitance plays an important role, the deep source/drain junctions can be beneficially made graded to reduce the junction capacitance.

One important feature of the present invention is that tips of the source/drain regions 28 under the gate can beneficially overlap with the boundary between gate dielectrics 18 and 24. In the case of an asymmetric undercut (described above) where the drain side undercut is made larger than that of the source side, the tip of source region beneficially overlaps with gate dielectric boundary 18 and 24 while the tip of drain region may or may not overlap with gate dielectric boundary 18 and 24.

In some embodiments of the present invention and when the substrate 12 does not include silicon, a Si-containing layer can be formed atop of the exposed portions of the substrate 12 to provide a source for forming the silicide contacts. Illustrative examples of Si-containing materials that can be used include, for example, Si, single crystal Si, polycrystalline Si, SiGe, and amorphous Si. This embodiment of the present invention is not illustrated in the drawings.

Next, the source/drain diffusion regions 28 are silicided utilizing a standard salicidation process well known in the art. This includes forming a metal capable of reacting with Si atop the entire structure, forming a barrier layer atop the metal, heating the structure to form a silicide, removing non-reacted metal and the barrier layer and, if needed, conducting a second heating step. The second heating step is required in those instances in which the first heating step does not form the lowest resistance phase of the silicide. In FIG. 1E, reference numeral 30 denotes the silicided source/drain regions. Note that if the gate conductor 20 is comprised of polysilicon or SiGe and the second gate oxide 26 is removed from its upper horizontal surface, this step of the present can be used in forming a metal silicide atop the Si-containing gate conductor. The latter embodiment is not specifically shown in the drawings of the present application.

At this point of the present invention, conventional back-end-of-the-line processes can be employed to form contacts to the silicided source/drain regions 30 as well as the gate conductor 20.

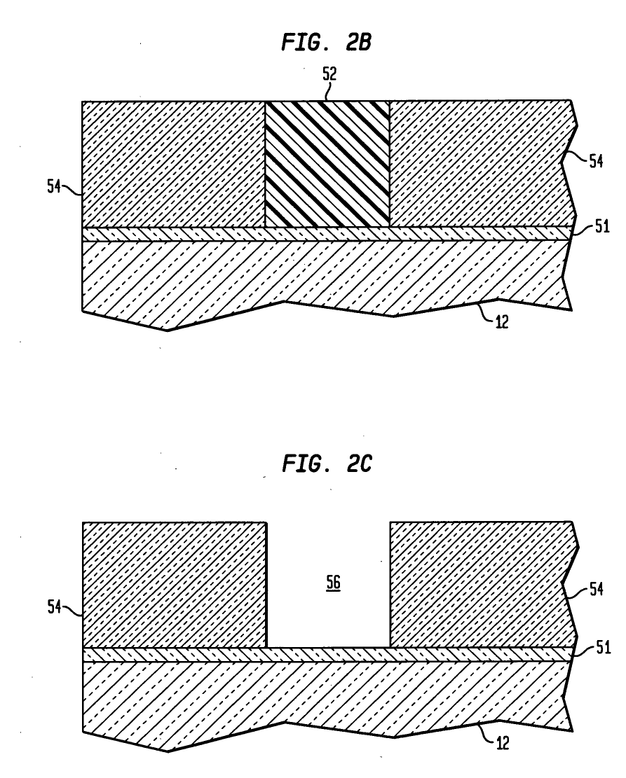

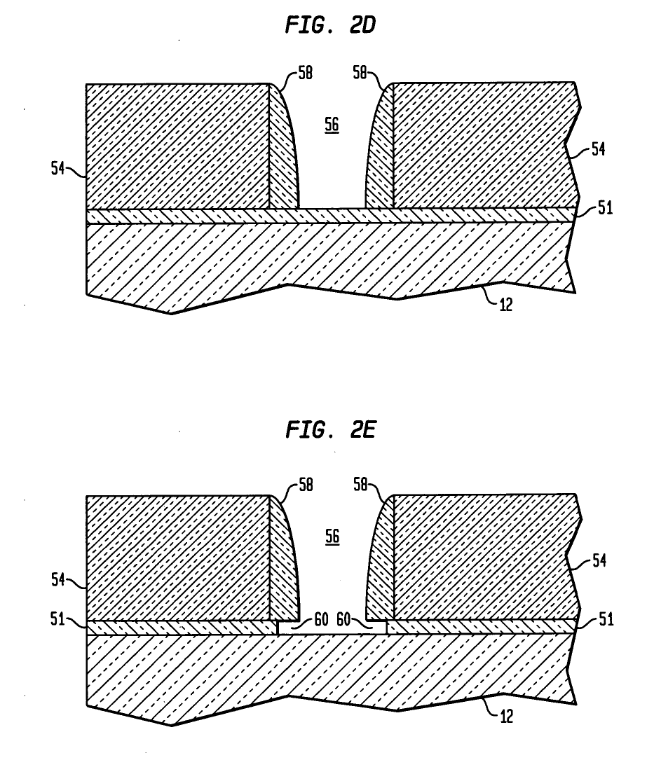

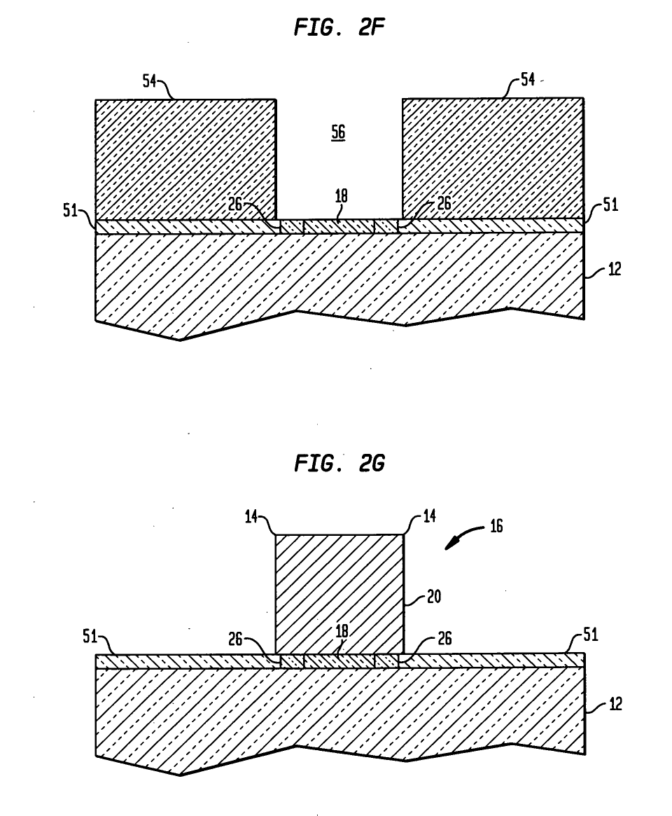

In addition to using the above method of the present invention, the present invention also contemplates a replacement gate method as depicted in FIGS. 2A-2G. This method of the present invention begins by first providing the structure 50 shown in FIG. 2A. Structure 50 includes a semiconductor substrate 12 that includes blanket layers of a sacrificial oxide 51 and a sacrificial polysilicon 52 located on a surface thereof. The sacrificial polysilicon layer 52 is formed utilizing a deposition process similar to that used in forming the gate conductor 20 and the thickness of layer 52 is also similar to that described above in regard to gate conductor 20. The sacrificial oxide 51 has the same thickness as that of the first and second gate oxides and it is formed using the gate oxide formation processes described above.

Next, the sacrificial polysilicon layer 52 is patterned by lithography and etching. The width of the patterned sacrificial layer 52 will determine the maximum channel length of the FET.

Source/drain extension implants and optional halo implants (both not shown) are then typically formed into the substrate 12 utilizing conventional source/drain extension implants and conventional halo implants. Each implant region may be activated using the same or different activation annealing process. The source/drain conditions and the annealing conditions are chosen to give a correct overlap for high-performance transistor and to minimize any parasitic series resistance as alluded above.

A dielectric material 54 such as TEOS (tetraethylorthosilicate) is then formed by a conventional deposition process and the structure is planarized by a conventional planarization process such as chemical mechanical polishing (CMP) or grinding so as to provide the structure shown in FIG. 2B. As illustrated, the dielectric material 54 has an upper surface that is coplanar with the upper surface of the patterned sacrificial polysilicon layer 52.

The patterned sacrificial polysilicon layer 52 is then removed from the structure so as to provide opening 56 that exposes a portion of the sacrificial oxide 51. The structure formed after removing the patterned sacrificial polysilicon layer 52 is shown, for example, in FIG. 2C. The patterned sacrificial polysilicon layer 52 may be removed utilizing chemical downstream etching or a wet etching process may be utilized in removing the patterned sacrificial polysilicon layer 52.

Next, optional device channel/body implantation is typically performed to alter the device's channel/body region in the substrate. This optional step can be used to beneficially alter threshold voltage as a function of opening size thus reducing short channel effects. This implant step of the present invention includes the use of conventional ion implantation. After implantation of the device channel/body region, the implant region is annealed using conditions well known to those skilled in the art. The implanted dopants will need additional activation that may undesirably alter the design of source/drain and, more specifically, the amount of source/drain gate overlap. Accordingly, in this case, the most desired activation anneal is an ultra short anneal such as laser or flash lamp anneal which activates dopants without much diffusion.

FIG. 2D shows the structure that is formed after a sacrificial spacer 58 is formed on the exposed vertical sidewalls of the dielectric material 54 in opening 56. The sacrificial spacer 58 is comprised of an insulator material other than an oxide, for example SiN. The sacrificial spacer 58 is formed by deposition and etching. The thickness of the sacrificial spacer 58 is typically from about 0.5 to about 5 nm.

The exposed portion of the sacrificial oxide 51 in opening 56 is then removed so as to provide the structure shown, for example, in FIG. 2E. Specifically, the exposed portion of the sacrificial oxide 51 is removed utilizing a chemical oxide removal (COR) etching process wherein a vapor or, more preferably, a plasma of HF and NH₃ is employed as the etchant and low pressures (of about 6 millitorr or below) are used. Note that the COR etching provides an undercut 60 beneath the sacrificial spacer 58 and it exposes surface portions of the substrate 12.

Second gate oxide 26 is then formed on exposed surfaces of the substrate 12 in the opening 56 utilizing a conventional thermal growing process or deposition. The second gate oxide 26 fills the undercut 60 formed above and thereafter the second gate oxide 26, not protected by the sacrificial spacer 58, is removed by a selective etching process. The selective etch removes the exposed portions of the second gate oxide 26, while leaving the second gate oxide 26 beneath the sacrificial spacer 58. This etch also exposes a surface portion of the semiconductor substrate 12.

Next, the sacrificial spacer 58 is removed utilizing a conventional etching process that selectively removes the spacer 58. The first gate oxide 18 is then formed within the opening 56 atop the exposed portion of the semiconductor substrate 12 providing the structure shown in FIG. 2F.

Next, a gate conductor 20, as described above, is formed within the opening and atop both the first and second gate oxides, 18 and 26. Thereafter, the dielectric material 54 is removed providing the structure shown in FIG. 2G. The dielectric material 54 is removed via an etch back step in which a chemical etchant is employed.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising:
a semiconductor substrate having at least one overlaying gate conductor, each of said at least one overlaying gate conductors has vertical edges;
a first gate oxide located beneath said at least one overlaying gate conductor, said first gate oxide not extending beyond the vertical edges of said at least one overlaying gate conductor; and
a second gate oxide located beneath at least a portion of said at one overlaying gate conductor, wherein said first gate oxide and second gate oxide are selected from a high k oxide-containing material and a low k oxide-containing material, with the proviso that when the first gate oxide is high k, than the second gate oxide is low k, or when the first gate oxide is low k, than the second gate oxide is high k.

2. The semiconductor structure of claim 1 wherein said high k oxide-containing material has a dielectric constant of about 6.0 or greater.

3. The semiconductor structure of claim 2 wherein said high k oxide-containing material comprises silicon oxide doped with a transition metal atom, silicon oxynitride doped with a transition metal, an insulation metal oxide, a perovskite-type oxide or multilayers thereof.

4. The semiconductor structure of claim 1 wherein said low k oxide-containing material has a dielectric constant of less than 6.0.

5. The semiconductor structure of claim 4 wherein said low k oxide-containing material comprises SiO₂, SiON, or a carbon doped oxide comprising atoms of at least Si, C and O.

6. The semiconductor structure of claim 1 wherein said first gate oxide is a high k oxide-containing material, and said second gate oxide is a low k oxide-containing material.

7. The semiconductor structure of claim 1 wherein said first gate oxide is a low k oxide-containing material, and said second gate oxide is a high k oxide-containing material.

8. The semiconductor structure of claim 1 wherein said second gate oxide is also located on said vertical edges of said gate conductor as well as atop said gate conductor.

9. The semiconductor structure of claim 1 further comprising source/drain diffusion regions in said semiconductor substrate wherein said source/drain diffusion regions are separated by a channel and the position of the source/drain diffusion regions-to-channel junction is located about 1 to about 4 nm from the vertical edges of the gate conductors.

10. The semiconductor structure of claim 1 further comprising a drain undercut that is larger than a source undercut.

11. The semiconductor structure of claim 1 further comprising spacers adjacent to said gate conductor and abutting silicided source/drain regions.

12. A method of forming a semiconductor structure comprising:
providing a semiconductor substrate having at least one overlaying gate conductor and a first gate oxide located beneath said at least one overlaying gate conductor, each of said at least one overlaying gate conductors having vertical edges;
recessing said first gate oxide to provide an undercut region beneath each gate conductor; and
forming a second gate oxide in at least said undercut region, wherein said first gate oxide and second gate oxide are selected from high k oxide-containing materials and low k oxide-containing materials, with the proviso that when the first gate oxide is high k, than the second gate oxide is low k, or when the first gate oxide is low k, than the second gate oxide is high k.

13. The method of claim 12 wherein said high k oxide-containing material has a dielectric constant of about 6.0 or greater and said low k oxide-containing material has a dielectric constant of less than 6.0.

14. The method of claim 12 wherein said first gate oxide is a high k oxide-containing material, and said second gate oxide is a low k oxide-containing material.

15. The method of claim 12 wherein said first gate oxide is a low k oxide-containing material, and said second gate oxide is a high k oxide-containing material.

16. A method of forming a semiconductor structure comprising:
providing a planarized structure comprising a semiconductor substrate, a sacrificial oxide on said semiconductor substrate, a patterned sacrificial polysilicon region on a portion of said sacrificial oxide and a dielectric material on other portions of said sacrificial oxide; removing said patterned sacrificial polysilicon region to provide an opening in said planarized structure and to expose a surface portion of the sacrificial oxide; forming a sacrificial spacer on sidewalls of said dielectric material in said opening;
removing said exposed surface portion of the sacrificial oxide from said opening so as to form an undercut beneath said sacrificial spacer;
forming a second gate oxide that fills said undercut;
forming a first gate oxide in said opening on exposed surface portions of said semiconductor substrate;
removing said sacrificial spacer;
forming a gate conductor in said opening; and
etching back at least said dielectric material.

17. The method of claim 16 wherein said high k oxide-containing material has a dielectric constant of about 6.0 or greater and said low k oxide-containing material has a dielectric constant of less than 6.0.

18. The method of claim 16 wherein said first gate oxide is a high k oxide-containing material, and said second gate oxide is a low k oxide-containing material.

19. The method of claim 16 wherein said first gate oxide is a low k oxide-containing material, and said second gate oxide is a high k oxide-containing material.
